(19) United States
(12) Patent Application Publication
(10) Pub. No.: US 2016/0284925 A1
(43) Pub. Date: Sep. 29, 2016

(54) DEPTH CONTROL FOR SCRIBING SEMICONDUCTOR DEVICES

(71) Applicant: Gabriel Harley, Mountain View, CA (US)

(72) Inventor: Gabriel Harley, Mountain View, CA (US)

(21) Appl. No.: 14/672,070

(22) Filed: Mar. 27, 2015

(51) Int. Cl. H01L 31/18; H01L 31/0236

(52) U.S. Cl. CPC H01L 31/186; H01L 31/02366

(57) ABSTRACT

Solar cells, including those having a plurality of sub-cells coupled by metallization structures, can include scribed silicon. Fabricating such solar cells can include forming a metallization structure on a first surface of a semiconductor substrate. It can also include measuring a parameter with the solar cell or otherwise analyzing the solar cell. The semiconductor substrate can be scribed from a second, opposite surface until the measured parameter reaches a threshold value.

### BACKGROUND

Photovoltaic cells, commonly known as solar cells, are devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

### BRIEF DESCRIPTION OF THE DRAWINGS

FIG. 1 illustrates a cross-sectional view of a solar cell prior to singulation to form physically separated sub-cells, in accordance with an embodiment of the present disclosure.

FIG. 2 illustrates a cross-sectional view of a solar cell subsequent to singulation to form physically separated sub-cells, in accordance with an embodiment of the present disclosure.

FIG. 3 illustrates a plan view from the metallization side of a solar cell that has been diced into four parallel connected sub-cells, in accordance with an embodiment of the present disclosure.

FIG. 4 illustrates a plan view from the metallization side of a solar cell that has been diced into two sub-cells in an in series arrangement, in accordance with an embodiment of the present disclosure.

FIG. 5 is a flowchart representing operations in a method of fabricating a solar cell using a depth control technique, in accordance with an embodiment of the present disclosure.

FIGS. 6-10 illustrate cross-sectional views of various examples of scribe depths, according to some embodiments.

FIGS. 11-12 illustrate example graphs of parameters and the parameters' respective relationships to scribe depth, according to some embodiments.

FIG. 13 illustrate a diagram of an example apparatus configured to perform the disclosed scribing with depth control, according to some embodiments.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” sub-cell does not necessarily imply that this sub-cell is the first sub-cell in a sequence; instead the term “first” is used to differentiate this sub-cell from another sub-cell (e.g., a “second” sub-cell).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as solar cell emitter region fabrication techniques, are not described in detail in order to not unnecessarily obscure embodiments of the present disclosure. Furthermore, it is to be understood that the various embodiments shown in the figures are illustrative representations and are not necessarily drawn to scale.

In certain circumstances, it can be beneficial to scribe a portion of the silicon for a semiconductor device. For example, one application is a multi-diode solar cell, which is also referred to herein as a solar cell having multiple sub-cells. In such an example, the silicon can be scribed to form multiple sub-cells that are connected together with a metallization structure. As another example, silicon can be scribed for stress relief and to inhibit crack formation in the semiconductor device. In those examples and others, the depth that is sufficient for one application (e.g., stress relief or crack inhibiting) may be different than that for another application (e.g., creating sub-cells). Moreover, in some instances, the surface of the substrate may be textured and therefore not uniform meaning that the scribe depth for one substrate may not be the same as the scribe depth for another substrate even in the same application. Accordingly, techniques and structures for achieving sufficient scribe depth for semiconductor devices yet reduce the risk of damage to the metallization structure are described.

Although much of the description focuses on multi-diode (e.g., sub-cells) solar cells for ease of understanding, in some embodiments, the disclosed techniques can be used in other applications. For example, as noted above, a single solar cell without sub-cells may benefit from scribing the silicon (e.g., to inhibit crack formation) and can further benefit from scribe depth control techniques. In another example, semiconductor devices other than solar cells (e.g., optoelectronics, LCDs, LEDs, OLEDs) can also benefit from the disclosed scribe depth control techniques.

The specification first describes an example multi-diode solar cell structure that can benefit from the disclosed scribing depth control. The specification then describes an example method for performing depth control followed by numerous examples. Finally, the specification describes an example apparatus configured to perform depth control.

To give context for a solar cell having a plurality of sub-cells, a single solar cell (e.g., 125 cm, 156 cm, 210 cm) can be subdivided into smaller cells to allow for flexibility in module current and voltage, as well as flexibility in the metallization (e.g., thickness can be reduced with reduced current). As an example, a single silicon P/N diode has an open circuit voltage (Voc) of 0.6 to 0.74 V. A maximum power voltage (Vmp) may be approximately 0.63V for a solar cell. Thus, single diode cells will have a voltage of 0.63V. If 10 sub-diodes are produced on a single full-area wafer, and connected in series, the voltage would be 6.3V for the entire cell (at roughly 1/10^{th} the current, or about 0.5 A for a standard cell).

As described in greater detail below in association with the Figures, specific embodiments described herein can be implemented based on the understanding that metal or metallization structures having a thickness of greater than approximately 20 microns can be used to prevent power loss otherwise associated with silicon (Si)-cracking in a solar cell by using the metal to hold the cell together. Embodiments described herein provide a metal structure (e.g., by plating, or foil, or ribbon, etc.) that is bonded to a full-area wafer having sub-cells. In the multi-sub-cell approach, the metal can be patterned such that the sub-cell interconnects are formed in the same operation as the sub-cell metallization and are part of the metallization structure of the full solar cell having the multiple sub-cells.

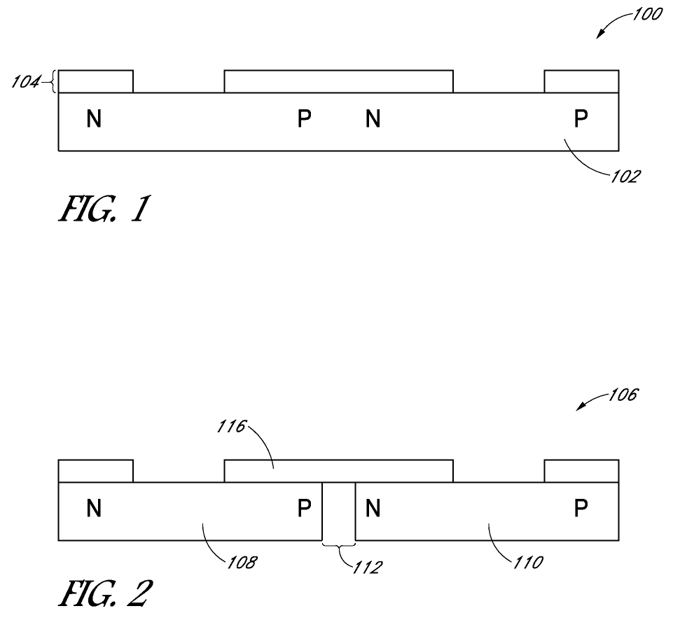

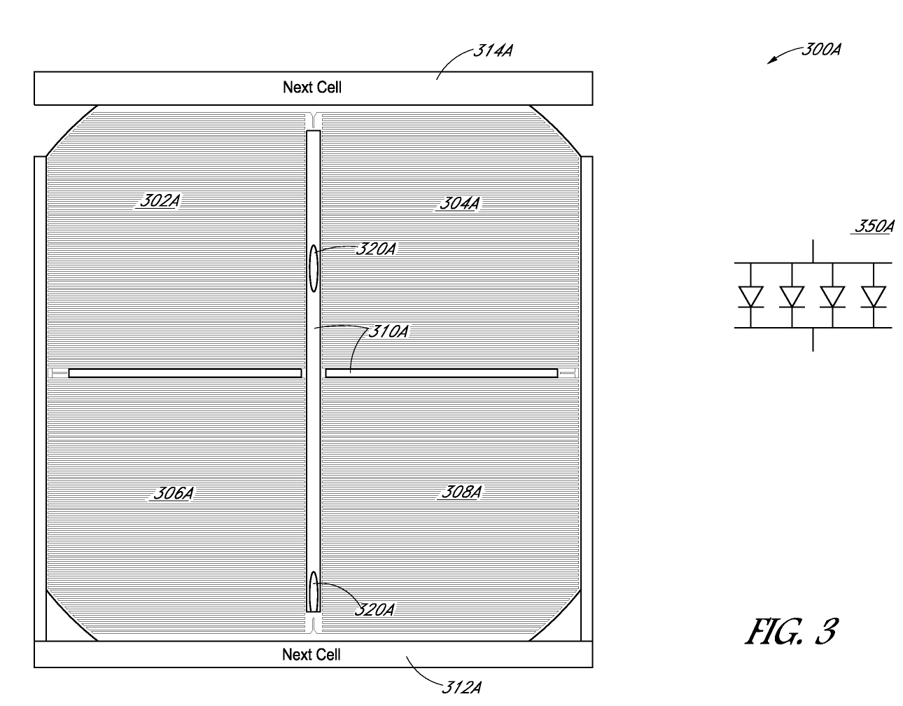

As an exemplary representation of the scribing concepts described herein, FIGS. 1 and 2 illustrate cross-sectional views of a solar cell prior to and subsequent to, respectively, singulation to form physically separated sub-cells, in accordance with an embodiment of the present disclosure.

Referring to FIG. 1, solar cell 100 can include substrate 102 having metallization structure 104 disposed thereon. Solar cell 100 can include alternating N-type and P-type regions in or above substrate 102. In one embodiment, metallization structure 104 is a monolithic metallization structure, as is described in greater detail below. Referring to FIG. 2, solar cell 100 has been singulated or diced to provide solar cell 106 having sub-cells 108 and 110 which are physically separated from one another. In one embodiment, solar cell 100 is singulated using laser ablation, which is described in greater detail below. In an embodiment, as is also depicted in FIG. 2, portion 116 of metallization structure 104 bridges two sub-cells 108 and 110. In a particular embodiment, sub-cells 108 and 110 provide series or parallel diode structures, examples of which are described in detail below.

Referring again to FIGS. 1 and 2, portion 116 of metallization structure 104 is used as both mechanical support and a back-stop during dicing, e.g., during laser ablation of substrate 102 material. In a first particular example, FIG. 2 illustrates a cross-sections view of a portion of a pair of singulated sub-cells using metal as a back-stop for cell singulation, in accordance with an embodiment of the present disclosure. As shown in FIG. 2, sub-cells 108 and 110 are formed upon singulation of substrate 102, having groove 112 there between. Portion 116 of the metallization structure 104 can be formed directly on the back surface of substrate 102 and, as such, a metal or metallic region is used as a back-stop during singulation.

In the example of FIG. 2, it is to be appreciated that, in an embodiment, metallization structure 104 can be viewed as a monolithic metallization structure, as described in greater detail below. Furthermore, in an embodiment, in either case, a sub-cell interconnect is fabricated in a same operation as the sub-cell metal. Alternatively, a sub-cell interconnect may be externally applied, but additional processing operations would be needed.

Referring again to FIGS. 1 and 2, more generally, in an embodiment, a solar cell includes a plurality of sub-cells. Each of the sub-cells can have a singulated and physically separated semiconductor substrate portion. Adjacent ones of the singulated and physically separated semiconductor substrate portions can have a groove there between. The solar cell can also include a metallization structure. A portion of the metallization structure couples ones of the plurality of sub-cells. Furthermore, the groove between adjacent ones of the singulated and physically separated semiconductor substrate portions exposes a portion of the metallization structure.

In an embodiment, the metallization structure is fabricated from a foil (e.g., a conductive foil, such as an aluminum foil with or without an additional seed layer) or is fabricated by a plating process. The metallization structure may be fabricated by plating, printing, by use of a bonding procedure (e.g., in the case of a foil), or may be fabricated by a by a deposition, lithographic, and etch approach. In one such embodiment, in the case that a relatively thick (e.g., greater that approximately 25 microns) back metal is used, some tolerance for partial laser ablation into the metal may be accommodated. However, if a thin metallization structure is used (e.g., less than approximately 25 microns), ablation may need to be halted without any scribing of the metallization structure, so as to maintain the electrical and physical integrity of the metal required to survive reliability testing. Accordingly, in various embodiments, the disclosed techniques can provide a way to halt the scribing while inhibiting damage to the metallization structure.

In an embodiment, the metallization scheme is used to hold and provide mechanical integrity for the sub-cells together within the parent cell, such that additional handling complexity is not necessarily required when building the module, and the cells remain physically separated.

In one embodiment, the emitter is designed so that the scribe falls primarily or entirely within the N-doped region, which has a lower recombination rate when unpassivated than the unpassivated P-doped region, and therefore results in significantly less power loss. In another embodiment, the emitter and scribe are designed so that there is little or no intersection of the scribe with a P-N junction, since unpassivated junctions have significantly higher recombination resulting in more power loss.

In one embodiment, a buffer stop (e.g., a polymer such as polyimide) can be implemented in addition to the scribing depth control techniques, to provide a backup to inhibit damage to the metallization structure. The polymer can be globally deposited and then patterned or may be deposited only in desired, e.g., by printing. In other embodiments, such a buffer stop is composed of a dielectric material such as, but not limited to, silicon dioxide (SiO₂), silicon nitride (SiN) or silicon oxynitride (SiON). In one such embodiment, the dielectric material can be formed using a deposition technique such as, but not limited to, low pressure chemical vapor deposition (LPCVD), plasma enhanced chemical vapor deposition (PECVD), high density plasma chemical vapor deposition (HDPCVD) or physical vapor deposition (PVD).

It is to be appreciated that one or more embodiments described herein involve implementation of metallization that is single-level ‘monolithic’ across all sub-cells. Thus, the resulting cell metallization can be identical to the interconnect metallization and fabricated in the same process, at the same time. In one such embodiment, use of a monolithic metallization structure leads to implementation of cell isolation as completed subsequent all diodes being metallized. This is distinguished from conventional approaches where metallization is a multi-step process. In more particular embodiments, a monolithic metallization approach is implemented in conjunction with a buffer or protective layer over which the monolithic metallization structure is formed. Such embodiments can allow for ablation stop on the buffer or protective layer without exposing the metal itself.

In some embodiments, an encapsulating material, e.g., ethylene vinyl alcohol (EVA), poly-olefin, can be disposed in the groove between adjacent ones of the singulated and physically separated semiconductor substrate portions. In one such embodiment, the encapsulant provides shunt resistance as well as wear resistance between adjacent sub-cell portions.

In accordance with an embodiment of the present disclosure, each sub-cell of a diced solar cell has approximately a same voltage characteristic and approximately a same current characteristic. In an embodiment, the plurality of sub-cells is a plurality of in-parallel diodes, in-series diodes, or a combination thereof. In an embodiment, the solar cell and, hence, the sub-cell portions, is a back-contact solar cell, and the metallization structure is disposed on the back surface, opposite a light-receiving surface, of each of the singulated and physically separated semiconductor substrate portions. In one such embodiment, the back surface of each of the sub-cells has approximately a same surface area. In a particular embodiment, the light-receiving surface of each of the sub-cells is a texturized surface, as is described in greater detail below.

In accordance with an embodiment of the present disclosure, the semiconductor substrate portions can be bulk monocrystalline silicon substrate portions, such as fabricated from an N-type monocrystalline substrate. In one such embodiment, each silicon portion includes one or more N+ regions (e.g., phosphorous or arsenic doped regions) and one or more P+ regions (e.g., boron doped regions) formed in substrate itself. In other embodiments, each silicon portion includes one or more polycrystalline silicon N+ regions and one or more polycrystalline silicon P+ regions formed above a silicon substrate.

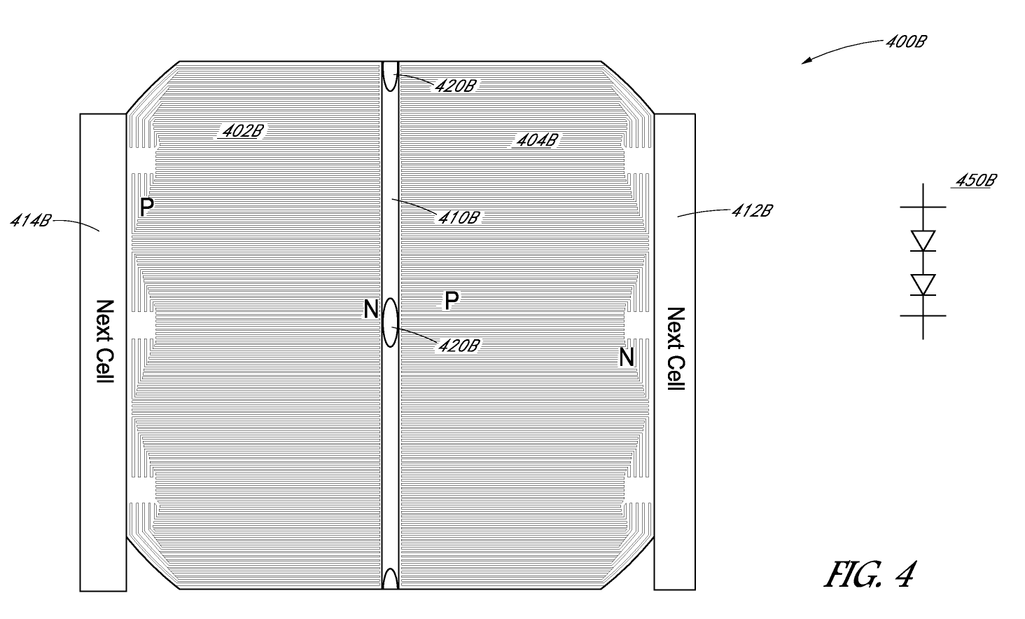

It is to be appreciated that a variety of arrangements of numbers and electrically coupling of sub-cells within a singulated solar cell may be contemplated within the spirit and scope of embodiments described herein. In a first example, FIG. 3 illustrates a plan view from the metallization side of solar cell 300A that has been diced into four sub-cells, in accordance with an embodiment of the present disclosure. Referring to FIG. 3, solar cell 300A is singulated to provide four sub-cells 302A, 304A, 306A and 308A. Metallization lines 310A are used to hold the quad-cell design together where each of the sub-cells meet. In one embodiment, stress-relief features 320A are included in the metallization lines 310A, as depicted in FIG. 3. Additionally, metallization coupling to a first next cell location 312A and a second next cell location 314A is depicted.

Referring again to FIG. 3, a diode schematic 350A illustrates the electrical configuration of the parallel quad-cell design. In an embodiment, the individual sub-cells are ¼ current of a single diode full cell, and have the same voltage as the single diode cell, whereas the combined 4-diode full cell has the same current, same voltage as full-size single diode cell. In one embodiment, the scribe cut can be performed on diffusion regions with the lowest recombination post isolation. The metal line length is ½ standard cell with ¼ cell bridging, which would enable either a reduction of metal thickness for the same size cell, or allow scaling to larger wafers without needing to increase the metal thickness.

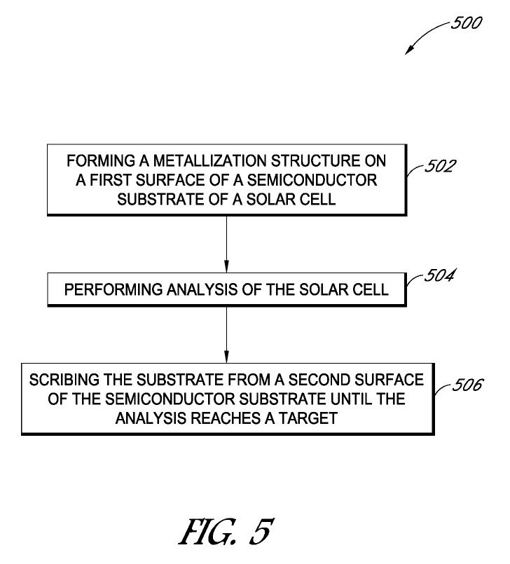

In another example, FIG. 4 illustrates a plan view from the metallization side of solar cell 400B that has been diced into two sub-cells in a series arrangement, in accordance with an embodiment of the present disclosure. Referring to FIG. 4, the solar cell 400B is singulated to provide two sub-cells 402B and 404B. Metallization line 410B is used to hold the dual-cell design together where each of the sub-cells meet. In one embodiment, stress-relief features 420B are included in metallization line 410B, as depicted in FIG. 4. Additionally, metallization coupling to a first next cell location 412B and a second next cell location 414B is depicted.

Referring again to FIG. 4, a diode schematic 450B illustrates the electrical configuration of the in series dual-cell design. In an embodiment, the sub-cells are ½ current of a single diode full cell, with the same voltage, with the combined full cell being ½ the current, but twice voltage of a single diode cell of the same size. In one embodiment, the scribe cut can be performed along the emitter junction. The metal line length is ½ standard cell to provide a single metal joint holding two half cells together.

With reference again to FIGS. 3 and 4, it is to be appreciated that a plurality of solar cells each singulated into sub-cells may be included in a photovoltaic (PV) module.

It is to be appreciated that other arrangements for sub-cells may also be achieved using approaches described herein, such as, but not limited to, 3×3, 4×4, etc., type arrangements. Also, a combination of series and parallel configurations of sub-cells within an original cell is also accessible. Approaches may be beneficial for both back contact and front contact based cells as well as other semiconductor devices.

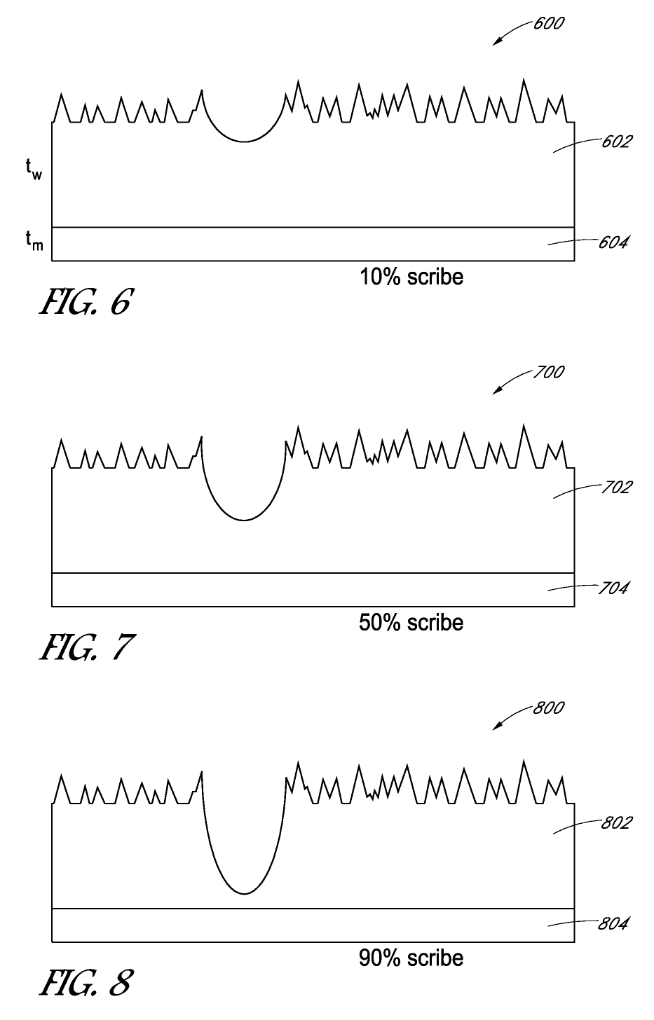

Turning now to FIG. 5, a flow chart illustrating a method for fabricating a solar cell using depth control is shown, according to some embodiments. In various embodiments, the method of FIG. 5 may include additional (or fewer) blocks than illustrated. For example, in one embodiment, the method can include placing the substrate on a curved chuck before scribing the substrate. Or, in another example, the method can include bending the substrate during or after scribing.

As shown at 502, a metallization structure can be formed on a first surface of a semiconductor substrate. In an embodiment, forming the metallization structure on the first surface of the semiconductor substrate involves patterning a metal foil formed on the first surface of the semiconductor substrate. In other embodiments, however, the metallization structure is formed by printing a metal, plating a metal or stack of metals, or by a metal deposition and etch process. In one embodiment, the metallization structure can be formed to have mechanical properties sufficient to bridge at least two sub-cells together through all reliability testing performed in the fabrication and test procedure.

In one embodiment, the metallization structure that is formed at 502 can be a metallization structure that bridges together multiple sub-cells of a parent solar cell. In another embodiment, the metallization structure can be the metallization structure for a single solar cell having a single diode.

As illustrated at 504, the solar cell can be analyzed. For example, the solar cell can be analyzed by measuring a parameter (e.g., current and/or voltage characteristics) of the solar cell (or sub-cells) or material parameters, by measuring reflective energy (e.g., intensity, wavelength) from a laser performing the scribing (or from another source, laser or otherwise), measuring the composition of the debris (plume) cloud generated by the scribing process, among other examples. In some embodiments, multiple sub-cells in a multi-diode solar cell can be analyzed at substantially the same time (e.g., probes on a chuck can correspond to respective ones of the sub-cells). In one embodiment, the measured parameter can be a shunt resistance and/or series resistance of the solar cell(s).

At 506, the substrate can be scribed from a second, opposite surface until the analysis reaches a target or threshold value. The resulting scribe can expose portions of the metallization structure from the second surface. Scribing can result in forming a plurality of sub-cells, each of the sub-cells comprising a singulated and physically separated portion of the substrate having a groove between adjacent ones of the singulated and physically separated substrate portions with the metallization structure coupling ones of the sub-cells.

As one particular example, if the analysis utilized to control the scribing depth is the shunt resistance of the solar cell or sub-cells, scribing can occur until the shunt resistance reaches a threshold value (e.g., 1000 ohm-cm²) at which point scribing can be stopped. An example graph 1200 of shunt resistance versus depth of cut is illustrated in FIG. 12. As shown in FIG. 12, the silicon-metal interface is represented by line 1204 and the shunt resistance is represented by curve 1202. As shown in the chart, an acceptable range 1206 for the multi-diode scribing is shown with the depth of cut with an acceptable shunt resistance being from almost to the silicon-metal interface to a depth that partially ablates into the metal. In one embodiment, the acceptable range for Rsh can be from 1000 to 50,000 ohm-cm². Note that for other applications (e.g., crack mitigation) or for other embodiments of the multi-diode solar cell (e.g., partial scribe then break), a different acceptable range may exist. Moreover, in some embodiments, the acceptable range may depend on materials of the semiconductor device, such as the substrate (e.g., P-type versus N-type substrate, polycrystalline versus monocrystalline substrate) or metallization (e.g., aluminum, copper, silver, tin, some combination thereof, etc.).

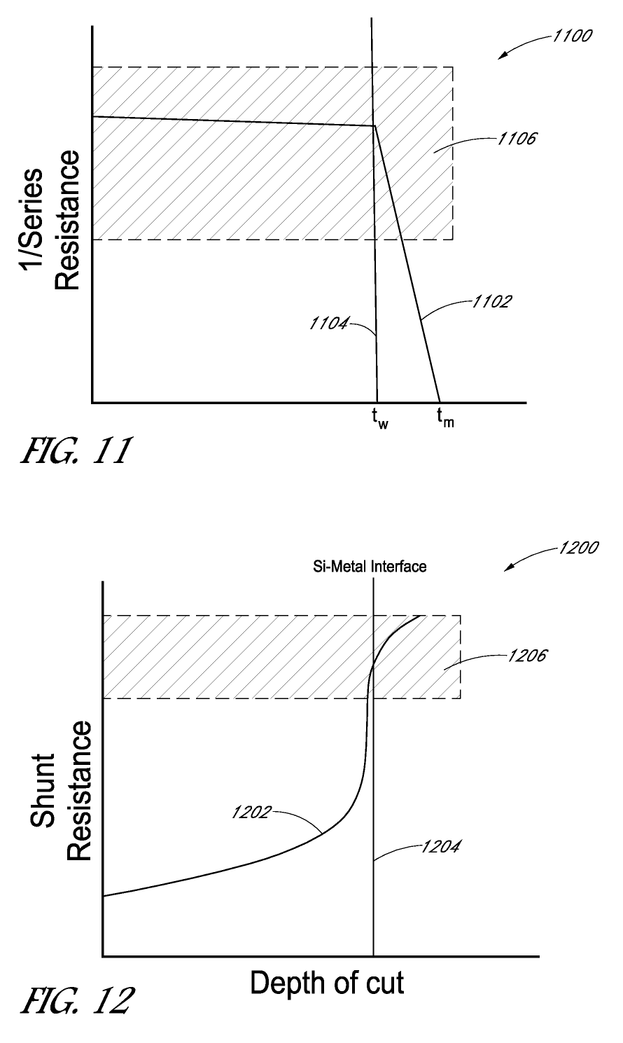

As another example, the analysis utilized to control scribing depth can be the series resistance of the solar cell or sub-cells. An example graph 1100 of series resistance versus depth of cut is illustrated in FIG. 11. As shown in FIG. 11, the silicon-metal interface is represented by line 1104 and the series resistance is represented by curve 1102. As shown in the chart, an acceptable range 1106 is shown. In one embodiment, the acceptable range (and therefore the threshold value) for series resistance can be from 0.3 to 1.0 ohm-cm². In contrast to the shunt resistance, though, the series resistance stays relatively constant until the point at which the silicon-metal interface 1104 is met, which makes the series resistance a less precise parameter from which to control the depth of the scribe if avoiding ablating any portion of the metallization structure is desired.

In some embodiments, the inflection point of the shunt and/or series resistance can be determined by taking the derivative of the slope of the shunt and/or series resistance, respectively. Stopping scribing of the tool can then be based on dRsh/dt and/or dRs/dt.

In some embodiments, the IV curve of the cell can be swept or the fill factor can be measured to not only monitor the scribe depth but to bin full cells, or complete a dice if one of the sub-cells is bad. Moreover, in some embodiments, the analysis can include imaging (e.g., EL, PL, hotspot testing) to identify and direct laser to cut-out or isolate defective regions of the device.

In an embodiment, the scribing is performed with a scribing instrument, such as a laser, of a tooling apparatus. Furthermore, in an embodiment, with the understanding that certain laser parameters may result in side-wall damage, melting, and disruption of the insulating dielectric stack on the rear side, the laser parameters can be selected so as to minimize such damage, melting, and disruption. Typically, this drives a laser selection to shorter pulse-lengths (e.g., less than approximately 10 nanoseconds), and processes that stop short of disrupting the rear dielectric (e.g., groove followed by mechanical separation).

It is to be appreciated that a mechanical scribing process, such as with a saw, milling machine, or etchant may be implemented instead of or in conjunction with a laser scribing process.

In various embodiments, scribing at 506 can occur at the same time the analysis or measuring occurs at 504 such that the scribing can be stopped quickly once the threshold value is achieved. For example, in one embodiment, the scribing instrument can receive, from a controller, an indication that the depth of the scribe is sufficient. In response to receiving the indication, the scribing instrument can then stop scribing.

In some embodiments, a partial scribe is performed, followed by breaking or sawing the substrate to complete isolation of portions of the substrate. In one embodiment bending the substrate can be performed during scribing, for example, by placing the substrate on a curved (e.g., concave, convex) chuck or surface for the scribing operation. In another embodiment, bending the substrate can be performed after scribing to complete the isolation of the substrate to the metallization structure. Manual breaking can help mitigate the risk of shunting through the base, e.g., by not totally isolating the Si, or having the isolated Si regions touch each other during cycling. In some embodiments, an encapsulant or dielectric can be applied in the gap to further mitigate the shunt risk.

In an embodiment, the method of cell fabrication further involves texturizing the second surface (light-receiving surface) of the semiconductor substrate prior to scribing the semiconductor substrate. Texturizing of the light-receiving surface of the solar cell can, in one embodiment, involve texturizing using a hydroxide-based etch process. It is to be appreciated that a texturized surface may be one which has a regular or an irregular shaped surface for scattering incoming light, decreasing the amount of light reflected off of the light-receiving surface of the solar cell. Accordingly, scribing the substrate at block 506 can include scribing a textured and non-uniform surface. Note also that other materials (e.g., the metallization structure) may also have variation in thickness. The disclosed techniques for depth control using analysis of the device can help accommodate variations in the non-uniform surface in contrast to a system that always scribes to a pre-determined depth.

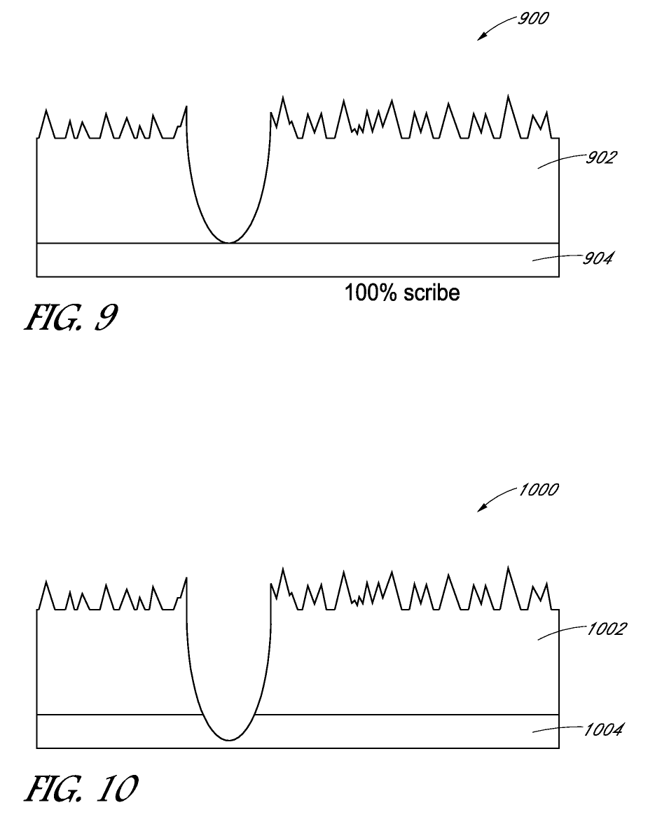

Turning now to FIGS. 6-10, cross-sectional views of various examples of scribe depths are shown. FIGS. 6-10 illustrate semiconductor device 600 (700, 800, 900, 1000) have a substrate 602 (702, 802, 902, 1002) and metallization structure 604 (704, 804, 904, 1004). FIG. 6 illustrates a 10% scribe where approximately 10% of the silicon depth t_{w} is scribed and none of the metallization structure depth tₘ is scribed. FIG. 7 illustrates a 50% scribe where approximately 50% of the silicon depth t_{w} is scribed and none of the metallization structure depth tₘ is scribed. FIG. 8 illustrates a 90% scribe where approximately 90% of the silicon depth t_{w} is scribed and none of the metallization structure depth tₘ is scribed. FIG. 9 illustrates a 100% scribe where approximately 100% of the silicon depth t_{w} is scribed and none of the metallization structure depth tₘ is scribed. FIG. 10 illustrates an over-scribe situation where approximately 100% of the silicon depth t_{w} is scribed and part of the metallization structure depth tₘ is scribed.

As described above, for certain applications, one scribe depth (e.g., 50%) may be sufficient whereas for other applications, as close to 100% scribe depth with scribing the metallization structure may be sufficient. In one embodiment, the silicon may first be scribed by the scribing instrument to a first depth followed by a manual breaking to achieve a second depth and/or the final resulting gap/isolation between the silicon portions.

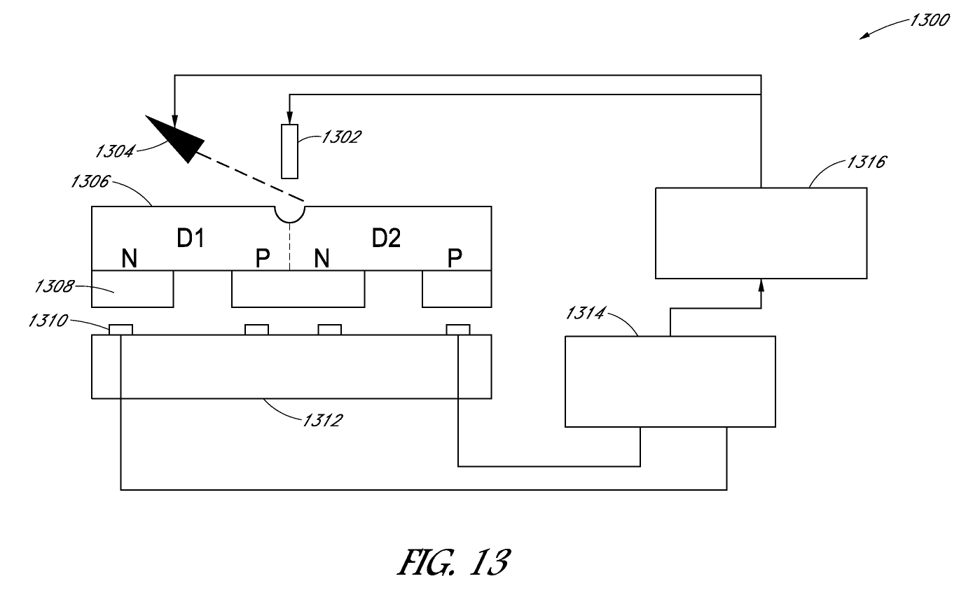

Turning now to FIG. 13, a tooling apparatus configured to perform the disclosed depth control techniques is illustrated, according to some embodiments. In the illustrated example, tooling apparatus 1300 includes controller 1316, test logic 1314, surface/chuck 1312, pins/probes 1310, and scribing instrument 1302. The example tooling apparatus of FIG. 13 also includes analytical tool 1304, which can be used instead of pins/probes 1310, or in addition to them. As shown a multi-diode solar cell 1306 have two diode, diode D1 and diode D2 is shown with metal regions 1308 positioned to be placed onto pins/probes 1310 of surface 1312.

In various embodiments, scribing instrument 1302 can be configured to scribe the substrate of semiconductor device 1306, as shown by the cut-out region under scribing instrument 1302. Scribing instrument can be a laser, saw, computer numerical control (CNC) milling machine, thermal-laser separation instrument, or an etchant instrument, (e.g., printed etchant, which can be applied/dosed based on the measured parameter), among other examples.

Surface/chuck 1312 can include pins/probes 1310 such that the chuck is configured to measure a parameter of the device 1306 and provide a parameter to controller 1316, via test logic 1314 or directly. Although not depicted in FIG. 13, surface/chuck 1312 can be a curved (e.g., concave, convex) chuck in other embodiments, which can help complete isolation between substrate portions and inhibit shunt risk.

In some embodiments, the test chuck of the tooling apparatus can be integrated into a cell testing system machine or be stand-alone.

In some embodiments, controller 1316 is configured to determine a depth of scribing of the substrate based on the analysis or parameter and send an indication to scribing instrument 1302 to stop scribing based on the determined depth.

Overall, although certain materials are described specifically above, some materials may be readily substituted with others with other such embodiments remaining within the spirit and scope of embodiments of the present disclosure. For example, in an embodiment, a different material substrate, such as a group III-V material substrate, can be used instead of a silicon substrate. In another embodiment, a polycrystalline or multi-crystalline silicon substrate is used. Furthermore, it is to be understood that, where N+ and P+ type regions are described specifically, other embodiments contemplated include a switched conductivity type, e.g., P+ and N+ type regions, respectively.

One or more benefits or advantages of embodiments described herein can include enabling greater precision in scribing a substrate having a non-uniform scribing surface, greater yield, and improved reliability without adding additional steps to the fabrication process.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A method of fabricating a solar cell, the method comprising:
forming a metallization structure on a first surface of a semiconductor substrate;
analyzing the solar cell; and
scribing the semiconductor substrate from a second, opposite, surface of the semiconductor substrate until the analysis reaches a threshold value.

2. The method of claim 1, wherein said analyzing the solar cell includes measuring a parameter including a shunt resistance of the solar cell, and wherein said scribing occurs until the shunt resistance reaches the threshold value.

3. The method of claim 1, wherein said scribing is performed during said measuring.

4. The method of claim 1, wherein said scribing the semiconductor substrate is performed with a laser.

5. The method of claim 1, further comprising bending the substrate after said scribing to complete isolation of the semiconductor substrate.

6. The method of claim 1, further comprising bending the substrate during said scribing to complete isolation of the semiconductor substrate.

7. The method of claim 1, further comprising placing the semiconductor substrate on a curved chuck, wherein said scribing is performed while the semiconductor substrate is on the curved chuck.

8. The method of claim 1, wherein said analyzing the solar cell includes measuring a current and voltage characteristics of the solar cell.

9. The method of claim 1, wherein said scribing the semiconductor substrate from the second, opposite, surface of the semiconductor substrate includes scribing a textured surface of the semiconductor substrate.

10. The method of claim 1, wherein said analyzing the solar cell includes measuring reflective energy from a laser performing said scribing, wherein said scribing is performed until the reflective energy reaches the threshold value.

11. The method of claim 1, further wherein said analyzing the solar cell includes analyzing a plume cloud associated with said scribing.

12. The method of claim 1, wherein the scribing comprises forming a plurality of sub-cells, each of the sub-cells comprising a singulated and physically separated portion of the semiconductor substrate having a groove between adjacent ones of the singulated and physically separated semiconductor substrate portions, wherein the metallization structure couples the plurality of sub-cells.

13. A solar cell fabricated according to the method of claim 1.

14. A method of fabricating a semiconductor device, comprising:
forming a metallization structure above a first surface of a semiconductor substrate of the semiconductor device;
a scribing instrument scribing the semiconductor substrate from a second, opposite, surface of the semiconductor substrate;
the scribing instrument receiving an indication that said scribing has reached a particular depth of the semiconductor substrate; and
the scribing instrument stopping said scribing in response to receiving the indication.

15. The method of claim 14, further comprising a controller sending the indication based on a measured value of the semiconductor device.

16. The method of claim 14, further comprising forming p-type and n-type doped regions in or above the first surface of the semiconductor substrate, wherein forming the metallization structure includes forming a patterned metallization structure coupled to the p-type and n-type doped regions.

17. A system for scribing a semiconductor substrate of a semiconductor device, the system comprising:
a scribing instrument configured to scribe the semiconductor substrate of a semiconductor device;
a chuck having probes, wherein the chuck is configured to measure a parameter of the semiconductor device and provide the parameter to a controller; and
the controller configured to determine a depth of scribing of the semiconductor substrate based on the parameter and to send an indication to the scribing instrument to stop scribing based on the depth.

18. The system of claim 17, wherein the scribing instrument is a laser.

19. The system of claim 17, wherein the parameter is a shunt resistance.

20. The system of claim 17, wherein the chuck is a curved chuck.
